(19) United States
(12) Patent Application Publication
(10) Pub. No.: US 2026/0371994 A1
(43) Pub. Date: Nov. 19, 2026

(54) SUBSTRATE COOLING SYSTEMS AND METHODS

(71) Applicant: ASM IP Holding B.V., Almere (NL)

(72) Inventor: Masaki Shimomura, Tokyo (JP)

(21) Appl. No.: 19/674,291

(22) Filed: May 12, 2026

Related U.S. Application Data
(60) Provisional application No. 63/806,085, filed on May 15, 2025.

(51) Int. Cl. H10P 72/00

(52) U.S. Cl. CPC H10P 72/0466; H10P 72/0454

(57) ABSTRACT

Substrate processing systems and methods include features relating to cooling substrates during manufacturing processes. Such processing systems and methods include features to enable the flow of coolant (e.g., cooling water) through a cooling station to be controlled so that coolant flows during limited times. As some examples, coolant flow through an individual cooling station may be limited to one or more of the following times: while a substrate is present at the cooling station; when a substrate arrives at the cooling station (or is scheduled to arrive at the cooling station); shortly before or shortly after a substrate arrives at the cooling station (or is scheduled to arrive); until a time when the substrate leaves the cooling station (or is scheduled to leave); and/or until a time shortly before or shortly after a substrate leaves the cooling station (or is scheduled to leave).

### CROSS-REFERENCE TO RELATED APPLICATIONS

This application claims priority to U.S. Provisional Patent Application Ser. No. 63/806,085 filed May 15, 2025 titled SUBSTRATE COOLING SYSTEMS AND METHODS, the disclosure of which is hereby incorporated by reference in its entirety.

### FIELD OF THE DISCLOSURE

The present disclosure relates generally to cooling systems and method, e.g., for use in substrate processing systems and methods.

### BACKGROUND OF THE DISCLOSURE

Material layers are commonly deposited onto substrates during fabrication of semiconductor devices, such as during fabrication of integrated circuits and electronic devices. Material layer deposition generally is accomplished by supporting a substrate within a substrate processing chamber arrangement, heating the substrate to a desired deposition temperature, and flowing one or more material layer precursors through the chamber arrangement and across the substrate. As the precursor flows across the substrate, the material layer progressively develops onto the surface of the substrate, typically according to the temperature of the substrate and environmental conditions within the chamber arrangement.

Conventional semiconductor production systems and methods of this type generally have been acceptable for their intended purpose, but there is room for improvement. Improvements that reduce costs and/or reduce material usage would be welcome advances in the art.

### SUMMARY OF THE DISCLOSURE

Aspects of this technology relate to cooling systems and methods, e.g., for use in semiconductor manufacture and/or manufacturing other substrates or components.

Substrate processing systems and methods in accordance with examples of this technology include features to enable the flow of coolant (e.g., cooling water) through a cooling system or cooling station to be controlled so that coolant does not flow continuously, but rather flows during limited times. As some examples, coolant flow through an individual cooling station may be limited to one or more of the following times: while a substrate is present at the cooling station; when a substrate arrives at the cooling station (or is scheduled to arrive at the cooling station); shortly before or shortly after a substrate arrives at the cooling station (or is scheduled to arrive); until a time when a substrate leaves the cooling station (or is scheduled to leave); and/or until a time shortly before or shortly after a substrate leaves the cooling station (or is scheduled to leave). When substrate processing systems and methods include multiple cooling stations and/or multiple cooling systems (e.g., multiple cooling stations and/or cooling systems in one or more different components of the substrate processing system), coolant flow to each individual cooling station may be independently controlled so that coolant flow is stopped and started based on when substrates are present (or are scheduled to be present) at that individual cooling station.

In other words, in examples of this technology, coolant flow within an individual cooling station: (i) will start at, shortly before, or shortly after the time a substrate arrives (or is scheduled to arrive) at the cooling station and (ii) will continue until, shortly before, or shortly after the time the substrate leaves (or is scheduled to leave) the cooling station. Flow of coolant within cooling systems in accordance with aspects of this technology is correlated to the presence and absence of a substrate (or the scheduled presence or absence of a substrate) in a specific individual cooling station.

Semiconductor or other substrate processing systems in accordance with at least some examples of this technology may include one or more of: (A) a substrate cooling system including a first substrate cooling station including: (i) a first substrate cooling plate, (ii) a first coolant inlet, (iii) a first coolant outlet, and (iv) a first heat conduction zone located between the first coolant inlet and the first coolant outlet, the first heat conduction zone configured to place coolant at a position to allow conductive heat transfer between the first substrate cooling plate and coolant located within the first heat conduction zone; (B) a first coolant supply line in fluid communication with the first coolant inlet; (C) a first valve changeable between: (a) an open configuration in which coolant flows through the first coolant supply line and into the first coolant inlet and (b) a closed configuration in which coolant flow through the first coolant supply line is stopped; and/or (D) a coolant supply control system programmed and configured: (i) to place the first valve in the open configuration in response to input data indicating that a substrate has moved to or will move to the first substrate cooling plate, and (ii) to place the first valve in the closed configuration in response to input data indicating that the substrate has moved or will move away from the first substrate cooling plate.

In addition to one or more of the features described above, or as an alternative, in at least some examples of this technology, the substrate cooling system may further include a second substrate cooling station including: (i) a second substrate cooling plate, (ii) a second coolant inlet, (iii) a second coolant outlet, and (iv) a second heat conduction zone located between the second coolant inlet and the second coolant outlet, the second heat conduction zone being configured to place coolant at a position to allow conductive heat transfer between the second substrate cooling plate and coolant located within the second heat conduction zone, and/or the substrate processing system may further comprise: (A) a second coolant supply line in fluid communication with the second coolant inlet of the second substrate cooling station; and (B) a second valve changeable between: (a) an open configuration in which coolant flows through the second coolant supply line and into the second coolant inlet and (b) a closed configuration in which coolant flow through the second coolant supply line is stopped, wherein the coolant supply control system further is programmed and configured: (i) to place the second valve in the open configuration in response to input data indicating that a substrate has moved to or will move to the second substrate cooling plate, and (ii) to place the second valve in the closed configuration in response to input data indicating that the substrate has moved or will move away from the second substrate cooling plate, and wherein the coolant supply control system controls the second valve independent of control of the first valve.

In addition to one or more of the features described above, or as an alternative, in at least some examples of this technology, the substrate processing system may further comprise one or more of: (A) a first load-lock module, wherein the first substrate cooling station and the second substrate cooling station are located within or directly accessible from the first load-lock module; (B) a first substrate handling chamber engaged with the first load-lock module; and/or (C) a first substrate transfer arm configured to move substrates between the first load-lock module and the first substrate handling chamber.

In addition to one or more of the features described above, or as an alternative, in at least some examples of this technology, the substrate processing system may further comprise one or more substrate processing chambers coupled with the first substrate handling chamber, wherein the first substrate transfer arm further is configured to move substrates between the first substrate handling chamber and the one or more substrate processing chambers.

In addition to one or more of the features described above, or as an alternative, in at least some examples of this technology, the substrate processing system may further comprise one or more of: (A) a second substrate handling chamber engaged with the first load-lock module; and/or (B) a second substrate transfer arm configured to move substrates between the first load-lock module and the second substrate handling chamber.

In addition to one or more of the features described above, or as an alternative, in at least some examples of this technology, the substrate processing system may further comprise a second load-lock module coupled with the first substrate handling chamber, wherein the first substrate transfer arm further is configured to move substrates between the first substrate handling chamber and the second load-lock module.

In addition to one or more of the features described above, or as an alternative, in at least some examples of this technology, the substrate processing system may further comprise a second substrate cooling system located within or directly accessible from the second load-lock module.

In addition to one or more of the features described above, or as an alternative, in at least some examples of this technology, the second substrate cooling system may include one or more of: (i) a second substrate cooling plate, (ii) a second coolant inlet, (iii) a second coolant outlet, and/or (iv) a second heat conduction zone located between the second coolant inlet and the second coolant outlet, the second heat conduction zone configured to place coolant at a position to allow conductive heat transfer between the second substrate cooling plate and coolant located within the second heat conduction zone; and/or the substrate processing system may further comprise: (A) a second coolant supply line in fluid communication with the second coolant inlet of the second substrate cooling station; and/or (B) a second valve changeable between: (1) an open configuration in which coolant flows through the second coolant supply line and into the second coolant inlet and (2) a closed configuration in which coolant flow through the second coolant supply line is stopped, and wherein the coolant supply control system may be further programmed and configured: (i) to place the second valve in the open configuration in response to input data indicating that a substrate has moved to or will move to the second substrate cooling plate, and (ii) to place the second valve in the closed configuration in response to input data indicating that the substrate has moved or will move away from the second substrate cooling plate.

Semiconductor or other substrate processing systems in accordance with at least some examples of this technology may include one or more of: (A) a substrate cooling system including:
a first substrate cooling station including: (i) a first substrate cooling plate, (ii) a first coolant inlet, (iii) a first coolant outlet, and (iv) a first heat conduction zone located between the first coolant inlet and the first coolant outlet, the first heat conduction zone configured to place coolant at a position to allow conductive heat transfer between the first substrate cooling plate and coolant located within the first heat conduction zone, and
a second substrate cooling station including: (i) a second substrate cooling plate, (ii) a second coolant inlet, (iii) a second coolant outlet, and (iv) a second heat conduction zone located between the second coolant inlet and the second coolant outlet, the second heat conduction zone configured to place coolant at a position to allow conductive heat transfer between the second substrate cooling plate and coolant located within the second heat conduction zone, and
(B) a first coolant supply line in fluid communication with the first coolant inlet; (C) a second coolant supply line in fluid communication with the second coolant inlet; (D) a first valve changeable between: (1) an open configuration in which coolant flows through the first coolant supply line and into the first coolant inlet and (2) a closed configuration in which coolant flow through the first coolant supply line is stopped; and (E) a second valve changeable between: (1) an open configuration in which coolant flows through the second coolant supply line and into the second coolant inlet and (2) a closed configuration in which coolant flow through the second coolant supply line is stopped.

In addition to one or more of the features described above, or as an alternative, in at least some examples of this technology, the substrate processing system may further comprise a coolant supply control system in electronic communication with the first valve and in electronic communication with the second valve, wherein the coolant supply control system is configured: (i) to change the first valve from the open configuration to the closed configuration in response to activity indicating a substrate has or will move away from the first substrate cooling plate, (ii) to change the first valve from the closed configuration to the open configuration in response to activity indicating a substrate has or will move to the first substrate cooling plate, (iii) to change the second valve from the open configuration to the closed configuration in response to activity indicating a substrate has or will move away from the second substrate cooling plate, and (iv) to change the second valve from the closed configuration to the open configuration in response to activity indicating a substrate has or will move to the second substrate cooling plate.

In addition to one or more of the features described above, or as an alternative, in at least some examples of this technology, the substrate processing system may further comprise one or more of: (A) a substrate transfer system configured: (1) to move substrates into and out of the first substrate cooling station, and (2) to move substrates into and out of the second substrate cooling station; and/or (B) a coolant supply control system in electronic communication with the first valve and in electronic communication with the second valve, wherein the coolant supply control system is configured: (i) to switch the first valve to the open configuration in response to input data indicating that the substrate transfer system has moved or will move a substrate to the first substrate cooling station, (ii) to switch the first valve to the closed configuration in response to input data indicating that the substrate transfer system has moved or will move a substrate out of the first substrate cooling station, (iii) to switch the second valve to the open configuration in response to input data indicating that the substrate transfer system has moved or will move a substrate to the second substrate cooling station, and (iv) to switch the second valve to the closed configuration in response to input data indicating that the substrate transfer system has moved or will move a substrate out of the second substrate cooling station.

In addition to one or more of the features described above, or as an alternative, in at least some examples of this technology, the substrate processing system may further comprise one or more of: (A) a first load-lock module, wherein the first substrate cooling station and the second substrate cooling station are located within or directly accessible from the first load-lock module; (B) a first substrate handling chamber engaged with the first load-lock module; and/or (C) a first substrate transfer arm configured to move substrates between the first load-lock module and the first substrate handling chamber.

In addition to one or more of the features described above, or as an alternative, in at least some examples of this technology, the substrate processing system may further comprise one or more substrate processing chambers coupled with the first substrate handling chamber, wherein the first substrate transfer arm further is configured to move substrates between the first substrate handling chamber and the one or more substrate processing chambers.

In addition to one or more of the features described above, or as an alternative, in at least some examples of this technology, the substrate processing system may further comprise one or more of: (A) a second substrate handling chamber engaged with the first load-lock module; and/or (B) a second substrate transfer arm configured to move substrates between the first load-lock module and the second substrate handling chamber.

In addition to one or more of the features described above, or as an alternative, in at least some examples of this technology, the substrate processing system may further comprise one or more additional substrate processing chambers coupled with the second substrate handling chamber, wherein the second substrate transfer arm further is configured to move substrates between the second substrate handling chamber and the one or more additional substrate processing chambers.

In addition to one or more of the features described above, or as an alternative, in at least some examples of this technology, the substrate processing system may further comprise a second load-lock module coupled with the first substrate handling chamber, wherein the first substrate transfer arm further is configured to move substrates between the first substrate handling chamber and the second load-lock module.

In addition to one or more of the features described above, or as an alternative, in at least some examples of this technology, the substrate processing system may further comprise a second substrate cooling system located within or directly accessible from the second load-lock module.

In addition to one or more of the features described above, or as an alternative, in at least some examples of this technology, the second substrate cooling system may include one or more of: (A) a third substrate cooling station including: (i) a third substrate cooling plate, (ii) a third coolant inlet, (iii) a third coolant outlet, and (iv) a third heat conduction zone located between the third coolant inlet and the third coolant outlet, the third heat conduction zone configured to place coolant at a position to allow conductive heat transfer between the third substrate cooling plate and coolant located within the third heat conduction zone; (B) a fourth substrate cooling station including: (i) a fourth substrate cooling plate, (ii) a fourth coolant inlet, (iii) a fourth coolant outlet, and (iv) a fourth heat conduction zone located between the fourth coolant inlet and the fourth coolant outlet, the fourth heat conduction zone configured to place coolant at a position to allow conductive heat transfer between the fourth substrate cooling plate and coolant located within the fourth heat conduction zone; (C) a third coolant supply line in fluid communication with the third coolant inlet of the third substrate cooling station; (D) a fourth coolant supply line in fluid communication with the fourth coolant inlet of the fourth substrate cooling station; (E) a third valve changeable between: (a) an open configuration in which coolant flows through the third coolant supply line and into the third coolant inlet and (b) a closed configuration in which coolant flow through the third coolant supply line is stopped; and/or (F) a fourth valve changeable between: (a) an open configuration in which coolant flows through the fourth coolant supply line and into the fourth coolant inlet and (b) a closed configuration in which coolant flow through the fourth coolant supply line is stopped.

Substrate processing methods, in accordance with at least some examples of this technology may comprise one or more of: (A) placing a first substrate in a first substrate transfer system; (B) moving the first substrate to a first substrate cooling station using the first substrate transfer system, wherein the first substrate cooling station includes a first substrate holding location and a first heat conduction zone; (C) activating coolant flow to move coolant through the first heat conduction zone in response to input data indicating that the first substrate has moved to or will move to the first substrate holding location; and/or (D) deactivating coolant flow through the first heat conduction zone in response to input data indicating that the first substrate has moved away from or will move away from the first substrate holding location.

In addition to one or more of the features described above, or as an alternative, in at least some examples of this technology, the substrate processing method may further comprise one or more of: (A) moving the first substrate away from the first substrate holding location using the first substrate transfer system at least in part while coolant flow through the first heat conduction zone is deactivated; (B) thereafter placing a second substrate in the first substrate transfer system; (C) moving the second substrate to the first substrate holding location using the first substrate transfer system; (D) activating coolant flow to move coolant through the first heat conduction zone in response to input data indicating that the second substrate has moved to or will move to the first substrate holding location; and/or (E) deactivating coolant flow through the first heat conduction zone in response to input data indicating that the second substrate has moved away from or will move away from the first substrate holding location.

In addition to one or more of the features described above, or as an alternative, in at least some examples of this technology, the substrate processing method may further include one or more of: (A) placing a second substrate in the first substrate transfer system; (B) moving the second substrate to a second substrate cooling station using the first substrate transfer system, the second substrate cooling station including a second substrate holding location and a second heat conduction zone; (C) activating coolant flow to move coolant through the second heat conduction zone in response to input data indicating that the second substrate has moved to or will move to the second substrate holding location; and (D) deactivating coolant flow through the second heat conduction zone in response to input data indicating that the second substrate has moved away from or will move away from the second substrate holding location.

In addition to one or more of the features described above, or as an alternative, in at least some examples of this technology, the substrate processing method may further comprise one or more of: (A) placing a second substrate in a second substrate transfer system; (B) moving the second substrate to a second substrate cooling station using the second substrate transfer system, wherein the second substrate cooling station includes a second substrate holding location and a second heat conduction zone; (C) activating coolant flow to move coolant through the second heat conduction zone in response to input data indicating that the second substrate has moved to or will move to the second substrate holding location; and/or (D) deactivating coolant flow through the second heat conduction zone in response to input data indicating that the second substrate has moved away from or will move away from the second substrate holding location.

In addition to one or more of the features described above, or as an alternative, in at least some examples of this technology, coolant flow through the second heat conduction zone may be controlled completely independent of control of coolant flow through the first heat conduction zone.

This summary is provided to introduce a selection of concepts relating to this technology in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 provides a schematic view of a substrate processing system according to some examples of this technology.

FIG. 2 provides a schematic view of a cooling system according to some examples of this technology.

FIG. 3 provides a flow chart describing cooling methods according to some examples of this technology.

FIG. 4 provides a schematic view of a cooling system according to some examples of this technology.

FIG. 5 provides a timing diagram illustrating operation of various components in systems and methods according to some examples of this technology.

FIG. 6 schematically illustrates features of systems and methods according to some additional examples of this technology.

FIG. 7 provides a schematic view of a substrate processing system according to some additional examples of this technology.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION

Reference now will be made to the drawings wherein like reference numerals identify similar structural features or aspects of the subject disclosure.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers.

A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may be unpatterned, such as a so-called “blanket-type” substrate. As examples, substrates in the form of a powder may have applications for pharmaceutical manufacturing. A porous substrate may include one or more polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

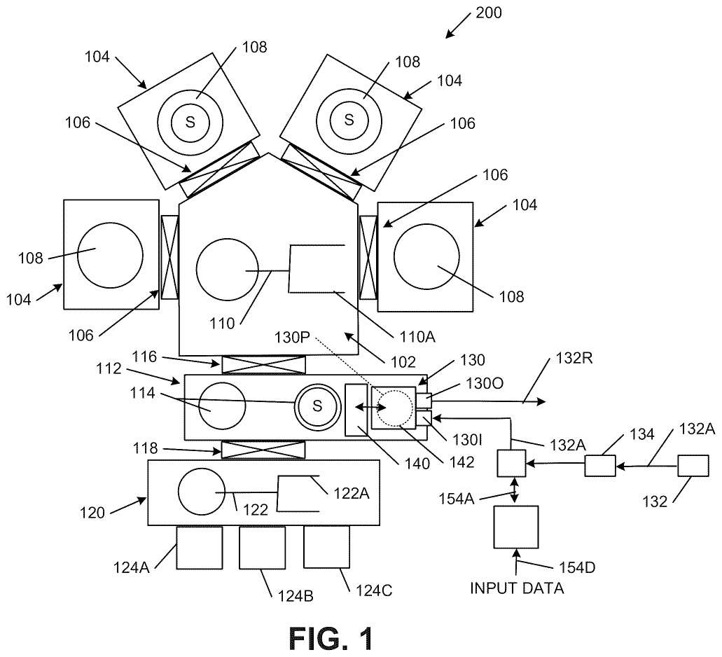

FIG. 1 schematically illustrates a substrate processing system 200 including a “cluster type” arrangement of components in accordance with some examples of this technology. Such substrate processing systems 200 include a substrate handling chamber 102 that operatively connects with and is engaged with two to four substrate processing chambers 104 via gate valves 106. Each substrate processing chamber 104 is equipped to receive a substrate S on a substrate support 108 that holds the substrate during processing (e.g., during material layer deposition).

The substrate handling chamber 102 includes robotic arm 110 used to move substrates into and out of the various substrate processing chambers 104 through the gate valves 106. In use, a gate valve 106 is opened, an end effector 110A of the robotic arm 110 extends through the open gate valve 106 to insert a substrate into or remove a substrate from an interior chamber of the substrate processing chamber 104 (e.g., placing a substrate on or taking a substrate off the substrate support 108). Once the robotic arm 110 is retracted from the substrate processing chamber 104, the gate valve 106 is closed, thereby sealing the substrate processing chamber 104 from the substrate handling chamber 102. Then, other desired actions can take place in the substrate processing chamber 104 and/or the substrate handling chamber 102, and different atmospheres and/or pressure conditions may be maintained in these chambers 102, 104.

FIG. 1 further shows that this substrate processing system 200 includes a load-lock module 112. The load-lock module 112 is connected with the substrate handling chamber 102 by gate valve 116. The load-lock module 112 includes substrate holding components 114 for holding substrates on the way into the substrate handling chamber 102 for further processing and on the way out of the substrate handling chamber 102 (after processing is complete). The end effector 110A of robotic arm 110 moves through the gate valve 116 (when opened) to move substrates from the load-lock module 112 into the substrate handling chamber 102 (for layer deposition and/or other processing) and from the substrate handling chamber 102 into the load-lock module 112 (after processing is completed). The load-lock module 112 and gate valve 116 keep the substrates isolated from the environment of the substrate handling chamber 102 until the conditions (e.g., temperature, pressure, content of atmosphere, etc.) within the substrate handling chamber 102 are ready for the substrate(s) to be inserted.

The load-lock module 112 further is coupled with an equipment front end module 120 via another gate valve 118. The equipment front end module 120 includes a robotic arm 122. The end effector 122A of that robotic arm 122 moves through the gate valve 118 (when opened) to move substrates from the equipment front end module 120 into the load-lock module 112 (for layer deposition and other processing) and from the load-lock module 112 into the equipment front end module 120 (after processing is completed). The robotic arm 122 of the equipment front end module 120 also picks up new substrates for processing from one of the load ports 124A-124C and returns processed substrates to one of the load ports 124A-124C, e.g., to be transported to another location for further processing.

The load-lock module 112 in substrate processing systems 200 of the type described in conjunction with FIG. 1 may include a substrate cooling system 130 at which substrates may be cooled (e.g., after processing). The cooling system 130 may be provided within or as part of the load-lock module 112, or it may be directly accessible from the load-lock module 112 (e.g., as a component connected to the load-lock module 112, such as via a gate valve arrangement). Coolant (e.g., water) is introduced into the cooling system 130 via coolant inlet 130I and removed from the cooling system 130 via coolant outlet 130O. The cooling system 130 may include a cooling plate 130P. Coolant (e.g., a fluid, such as water) from a coolant source 132 is supplied to coolant inlet 130I. A main coolant shutoff valve 134 may be provided, e.g., to allow coolant flow to the overall cooling system 130 to be stopped.

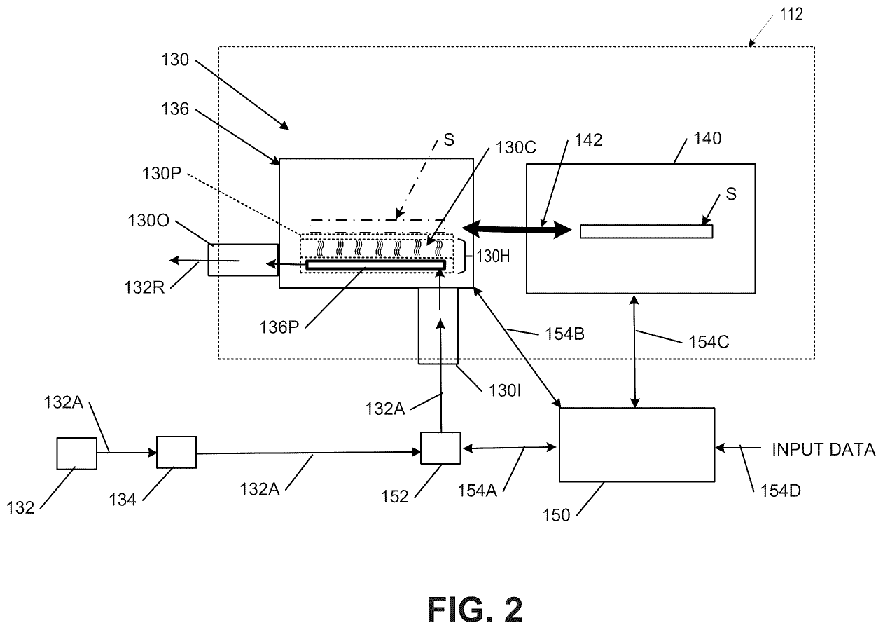

FIG. 1 and FIG. 2 schematically illustrate additional features of cooling system 130 and its connection to a coolant source 132 in accordance with aspects of this technology. Where the same reference number is used in FIG. 2 as used in FIG. 1, the same or similar part is being referenced, and much of the duplicative description thereof may be omitted.

In the examples of FIGS. 1 and 2, the cooling system includes a cooling station 136. One or more cooling stations 136 of this type may be provided in a single cooling system 130 and/or in a single load-lock module 112 in different specific examples of this technology. As shown in FIG. 2, this example cooling station 136 includes: (i) a substrate cooling plate 130P, (ii) the coolant inlet (e.g., 130I), (iii) the coolant outlet (e.g., 130O), and (iv) a heat conduction zone 130H located between the coolant inlet 130I and coolant outlet 130O.

The heat conduction zone 130H is configured to place coolant at a position to allow conductive heat transfer between the substrate cooling plate 130P and coolant located within the heat conduction zone 130H. As a more specific example, the heat conduction zone 130H may be formed to include at least one coolant flow pathway 136P through it, e.g., a tunnel, channel, and/or open space through which the coolant flows. The coolant inlet 130I introduces coolant into the coolant flow pathway 136P and the coolant outlet 130O removes coolant from the coolant flow pathway 136P. Within the coolant flow pathway 136P between the coolant inlet 130I and outlet 130O, the coolant contacts an upper surface of the heat conduction zone 130H that encloses the pathway 136P (e.g., the top surface of the tunnel, channel, and/or open space). At least some portion of the material making up the heat conduction zone 130H is formed from a heat conductive material (e.g., metal, metal alloy, etc.), and this material may be present in at least a conductive zone 130C located between the coolant flow pathway 136P and the cooling plate 130P. The cooling plate 130P may constitute the top surface of the heat conduction zone 130H (e.g., the top of conductive zone 130C), such as a cover, or it may constitute a separate part provided on the heat conduction zone 130H.

The coolant flow pathway 136P may have a coiled shape, a grid-like shape, a meandering shape, an enlarged open area, or other suitable shape between inlet 130I and outlet 130O. In at least some examples of this technology, the coolant flow pathway 136P will take an indirect passageway through the heat conduction zone 130H or otherwise open into a large area so that the coolant material within the pathway 136P is incident on a relatively large portion or proportion of the surface area of the material between the pathway 136P and the cooling plate 130P. This facilitates greater heat transfer from the coolant to the heat conduction zone 130H.

FIGS. 1 and 2 further illustrate that this example load-lock module 112 includes a substrate transfer system 140 (e.g., an indexer). The substrate transfer system 140 is configured to move substrates S into and out of the substrate cooling station 136, as generally shown by arrow 142 in FIG. 2. In some examples of this technology, the substrate transfer system 140 moves between a cooling position (where a substrate is located within the cooling station 136) and a transferring position (where a substrate is moved out of cooling station 136).

FIGS. 1 and 2 illustrate further features that may be included in systems and methods in accordance with examples of this technology. As shown, these illustrated example substrate processing systems 200 include: (i) a controllable valve 152 (receiving coolant from coolant source 132) and (ii) a coolant supply control system 150. The controllable valve 152 is changeable between: (a) an open configuration in which coolant flows through the coolant supply line 132A, through the controllable valve 152, and into the first coolant inlet 130I (thereby placing the coolant supply line 132A in fluid communication with the first coolant inlet 130I), and (b) a closed configuration in which coolant flow through the coolant supply line 132A and the controllable valve 152 is stopped.

The coolant supply control system 150 of this example: (i) receives input data (e.g., regarding the status of the substrate transfer system 140 and/or other data relating to whether a substrate S is present in the cooling station 136) and (ii) controls the controllable valve 152 based, at least in part, on the input data. More specifically, in some examples of this technology, the coolant supply control system 150 will be programmed and configured: (i) to place the controllable valve 152 in its open configuration (e.g., in response to input data indicating that a substrate S has moved to, is moving to, and/or will move to the substrate cooling plate 130P and/or in response to other data indicating that a substrate S is present in, is moving to, and/or has moved to the cooling station 136)), and (ii) to place the controllable valve 152 in its closed configuration (e.g., in response to input data indicating that a substrate S has moved, is moving, and/or will move away from the substrate cooling plate 130P and/or in response to other data indicating that no substrate S is present in the cooling station 136 and/or that a substrate has moved from, is moving from, or will move from the cooling station 136). Examples of operation of such systems and methods are described in more detail below.

In this illustrated example, the coolant supply control system 150 receives input data, e.g., from various sources, such as the controllable valve 152 (line 154A), the cooling system 130 (line 154B), the substrate transfer system 140 (line 154C), and/or other components of the substrate processing system 200 (e.g., scheduler data via line 154D), etc. The data may be transmitted to the coolant supply control system 150 in any suitable manner, e.g., via a wired or wireless connection, generally shown by data transmission lines 154A, 154B, 154C, and 154D in FIG. 2. Electronic communications between the coolant supply control system 150 and these other components may take place in any suitable manner (e.g., wired or wirelessly), using any suitable data transfer and/or communication format(s) and/or protocol(s).

The coolant supply control system 150 may comprise part of the overall computer control system hardware and/or software for operating the substrate processing system 200 and its corresponding methods; it may comprise part of the computer control system hardware and/or software for operating one or more other individual components of substrate processing system 200 and its corresponding methods; and/or it may (at least in part) comprise a separate computing system (optionally that receives data from and/or supplies data to the overall computer control system for operating the substrate processing system 200). The coolant supply control system 150: (a) may include hardware and/or software components to receive input data via one or more data input ports (e.g., one or more wired or wireless connection ports), such as data from one or more of controllable valve 152 position data, substrate transfer system 140 position data, cooling system 130 status data, data from a scheduler or other components of overall substrate processing system 200, etc.; (b) may include hardware and/or software components to further process and/or otherwise use that data (e.g., using one or more microprocessors operating suitable data processing algorithms); (c) may include hardware and/or software components to generate output; (d) may include hardware and/or software components to transmit output data, e.g., to one or more computer controllable devices (such data to controllable valve 152); and/or (e) may include hardware and/or software components to save data (e.g., input data, output data, intermediately calculated or processed data, etc.) in one or more computer memory systems. The coolant supply control system 150 may comprise a conventional programmable computer system that is programmed and adapted to operate and/or control components in accordance with aspects of the present technology described herein.

Operation of this example cooling system 130, coolant supply control system 150, controllable valve 152, and substrate processing system 200 in accordance with aspects of this technology will be described in more detail below.

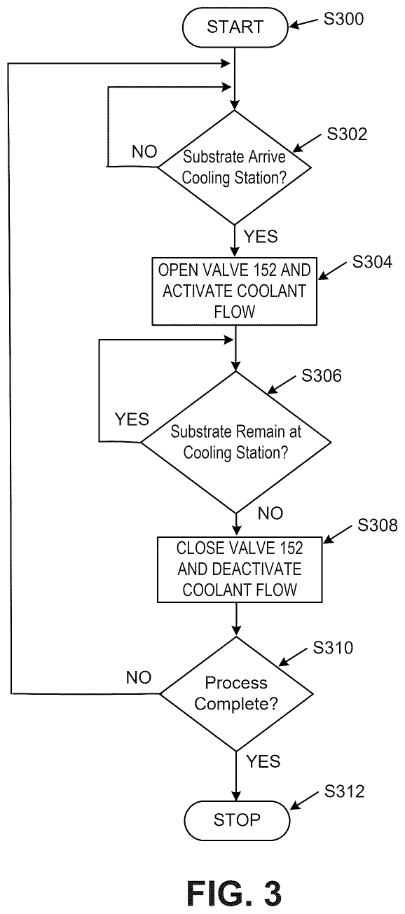

FIG. 3 illustrates features of some example systems and methods in accordance with this technology. As described above, in these systems and methods, substrates placed in a substrate transfer system 140 are moved into and out of the cooling system 130 (and into and out of cooling station 136 in the example of FIGS. 1 and 2). Thus, at the start (S300) of this example method, at Step S302, a determination is made as to whether a substrate has arrived at (or is on its way to) the cooling station 136. This determination may be accomplished in various ways and/or by various activities, such as by sending data from the substrate transfer system 140 to the coolant supply control system 150 (e.g., indexer position data), by sending data from the cooling station 136 to the coolant supply control system 150 (e.g., substrate sensor data associated with the cooling station 136), by receipt of scheduler data from the main substrate processing system 200 control system at the coolant supply control system 150 indicating when a substrate is scheduled to arrive at cooling station 136, etc.

If no substrate is present (and/or arriving and/or scheduled to arrive) at cooling station 136 at Step S302 (answer “NO”), the system and method return to Step S302 and repeat the check. If a substrate is present (or is scheduled to arrive) at the cooling station 136 at Step S302 (answer “YES”), at Step S304, the coolant supply control system 150 is activated to open controllable valve 152 and activate coolant flow so that coolant from the source 132 flows through the cooling station 136 to produce cooling at the cooling plate 130P (via heat conduction from the coolant pathway 136P through conductive zone 130C).

Valve 152 opening and coolant flow through controllable valve 152 and cooling station 136 at Step S304 need not be initiated precisely at a time when a substrate arrives at the cooling station 136 or sets on the cooling plate 130P. Coolant flow may begin at any suitable time in the process. As some examples, valve 152 opening and coolant flow may begin at any one or more of: (a) “shortly before” or “shortly after” a substrate arrives at the cooling stations 136 (e.g., with “shortly” as used in this context meaning ±5 seconds from when the substrate is set on the cooling plate 130P); (b) while a substrate is on the substrate transfer system 140 and moving toward the cooling station 136; (c) when the substrate is placed on the cooling plate 130P; (d) when scheduler data indicates that a substrate is scheduled to arrive at the cooling station 136; and/or (e) “shortly before” or “shortly after” a substrate is scheduled to arrive at the cooling station 136 (e.g., with “shortly” in this context meaning ±5 seconds from when the substrate is scheduled to arrive at the cooling station). In some specific examples of this technology, valve 152 opening and coolant flow may begin ±3 seconds, ±2 seconds, or ±1 second from when the substrate is set on the cooling plate 130P and/or ±3 seconds, ±2 seconds, or ±1 second from when the substrate is scheduled to arrive at the cooling station.

Next, this example system and method determine whether the substrate remains at the cooling station 136 at Step S306. This may be accomplished in various ways and/or by various activities, such as by sending data from the substrate transfer system 140 to the coolant supply control system 150 (e.g., indexer position data), by sending data from the cooling station 136 to the coolant supply control system 150 (e.g., substrate sensor data associated with the cooling station 136), by receipt of scheduler data from the main substrate processing system 200 control system at the coolant supply control system 150 indicating when a substrate is scheduled to leave the cooling station 136, etc.

If the substrate remains present at cooling station 136 at Step S306 (answer “YES”), the system and method return to Step S306 and repeat the check. At some point in time, however, the substrate will be moved from the cooling station 136 (or will be scheduled to move from the cooling station 136). Thus, if the substrate is leaving or has left the cooling station 136 (or is scheduled to leave)—answer NO at Step S306—at Step S308 the coolant supply control system 150 is activated to close controllable valve 152 and deactivate coolant flow so that coolant from the source 132 does not flow through the cooling station 136.

Valve 152 closing and coolant flow deactivation through controllable valve 152 and cooling station 136 at Step S308 need not be initiated precisely at a time when a substrate leaves at the cooling station 136 or is lifted from the cooling plate 130P. Coolant flow may be discontinued at any suitable time in the process. As some examples, valve 152 closing and coolant flow deactivation may begin at any one or more of: (a) “shortly before” or “shortly after” a substrate is moved out of the cooling station 136 (e.g., with “shortly” as used in this context meaning ±5 seconds from when the substrate is lifted from the cooling plate 130P); (b) while a substrate is on the substrate transfer system 140 and is moving away from the cooling station 136; (c) when the substrate is lifted from the cooling plate 130P; (d) when scheduler data indicates that a substrate is scheduled to leave the cooling station 136; and/or (e) “shortly before” or “shortly after” a substrate is scheduled to leave the cooling station 136 (e.g., with “shortly” in this context meaning ±5 seconds from when the substrate is scheduled to leave the cooling station). In some specific examples of this technology, valve 152 closing and coolant flow deactivation may begin ±3 seconds, ±2 seconds, or ±1 second from when the substrate is lifted from the cooling plate 130P and/or ±3 seconds, ±2 seconds, or ±1 second from when the substrate is scheduled to leave at the cooling station.

As Step S310, this example system and method then check whether overall substrate processing has been completed, e.g., whether the overall substrate processing system 200 continues operating on other substrates or whether the substrate processing system 200 is shutting down. If all processing is complete (answer “YES” at Step S310), no further cooling should be needed, and the process stops (S312). If substrate processing is not complete (answer “NO” at Step S310), e.g., if the substrate processing system 200 continues operating on other substrates within the overall substrate processing system 200, the process returns to Step S302 and waits for a new substrate to arrive at cooling station 136. And the process then repeats (e.g., with new substrates moved into and out of the cooling station 136 via substrate transfer system 140) until all processing is complete (answer “YES”) at Step S310.

In this manner, coolant flows through the cooling station 136 only during and/or around the time periods when a substrate is present (or is scheduled to be present) in the cooling station 136. In some examples, coolant flow will be deactivated and/or will have stopped shortly before the substrate transfer system 140 moves the substrate out of the cooling station 136, while the substrate transfer system 140 is moving the substrate out, or shortly after the substrate transfer system 140 has moved the substrate out of the cooling station 136. These features reduce the volume of coolant used and/or moved during the course of substrate processing.

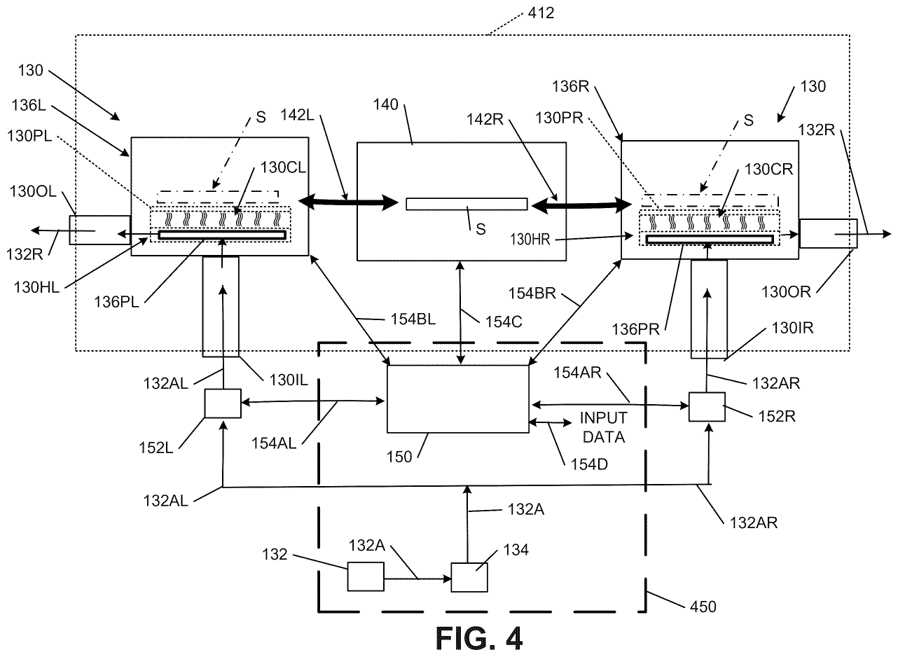

FIGS. 1-3 describe systems and methods having a single cooling system 130 and a single cooling station 136 in load-lock module 112. In some examples of this technology, however, a single load-lock module 412 may include a second cooling station 136 therein. FIG. 4 schematically illustrates one example of such a load-lock module 412 that includes a cooling system 130 having: (i) a left side cooling station 136L and (ii) a right side cooling station 136R.

In the example load-lock module 412 and system shown in FIG. 4, the same root reference numbers (“XXX” or “XXXY”) are used as used in describing the examples of FIGS. 1 and 3. But in the example of FIG. 4, for some components: (i) an “L” designator (“XXXL” or “XXXYL”) is added to the root reference number to signify that the component or part is part of the left side cooling station 136L and (ii) an “R” designator (“XXXR” or “XXXYR”) is added to the root reference number to signify that the component or part is part of the right side cooling station 136R. Where the same reference number or reference number root is used in FIG. 4 as used for the reference numbers in FIGS. 1-3, the same or similar part is being referenced (including any features, options, or alternatives for that part), and much of the duplicative description thereof may be omitted.

In the example load-lock module 412 shown in FIG. 4, both the left cooling station 136L and the right cooling station 136R are supplied with coolant (e.g., water) from the same source 132 (via coolant supply line 132A splitting into lines 132AL and 132AR, respectively, thereby placing the coolant supply line 132A in fluid communication with fluid inlets 130IL and 130IR, respectively). Additionally, in this illustrated example, both the left cooling station 136L and the right cooling station 136R are in communication with (e.g., transmit data to and receive data from) a single coolant supply control system 150 (e.g., via data transmission lines 154BL and 154BR, respectively). Also, in this illustrated example, both the left cooling station 136L and the right cooling station 136R are serviced by a single substrate transfer system 140 (which shares time to move substrates S into and out of the left cooling station 136L and into and out of the right cooling station 136R). Note substrate transfer arrows 142L and 142R. Each of the cooling stations 136L and 136R may be independently in electronic communication with coolant supply control system 150, e.g., via data transmission lines 154BL and 154BR.

Each of the left side cooling station 136L and the right side cooling station 136R of this example receives incoming coolant via its own, dedicated, controllable valve—152L and 152R, respectively. These controllable valves 152L and 152R are individually and independently controlled by coolant supply control system 150, e.g., via commands sent over data transmission lines 154AL and 154AR, respectively. Thus, the controllable valves 152L and 152R may be opened and closed independent of one another. More specifically, in this example system (e.g., load-lock module 412), at any given time: (i) both controllable valves 152L and 152R may be in their open configuration, (ii) both controllable valves 152L and 152R may be in their closed configuration, (iii) controllable valve 152L may be in its open configuration while controllable valve 152R is in its closed configuration, or (iv) controllable valve 152L may be in its closed configuration while controllable valve 152R is in its open configuration. In this manner, at any given time: (i) coolant may be flowing through both the left cooling station 136L and the right cooling station 136R, (ii) coolant flow may be stopped in both the left cooling station 136L and the right cooling station 136R, (iii) coolant may be flowing through the left cooling station 136L but not flowing through the right cooling station 136R, or (iv) coolant may be flowing through the right cooling station 136R but not flowing through the left cooling station 136L.

Further, in the example of FIG. 4, the left side cooling station 136L and the right side cooling station 136R operate independently and in parallel (operating simultaneously), although use of the substrate transfer system 140 is shared (e.g., a controlled, for example, by scheduler software operating the overall substrate processing system 200 and/or operating the load-lock module 412). As a more specific example, each of the left side cooling station 136L and the right side cooling station 136R may operate independently and in parallel (operating simultaneously) using the method algorithm generally described above in conjunction with FIG. 3. In this manner, coolant flows through the left cooling station 136L only during and/or around the time periods when a substrate is present (or scheduled to be present) in that left cooling station 136L and coolant flows through the right cooling station 136R only during and/or around the time periods when a substrate is present (or scheduled to be present) in that right cooling station 136R. “Around” the time period, as used in this context, has the same meaning as “shortly” described above (±5 seconds, and in some specific examples, ±3 seconds, ±2 seconds, or ±1 second).

By separately controlling controllable valves 152L and 152R (using coolant supply control system 150), coolant flow can be independently deactivated and/or will have stopped: (A) shortly before the substrate transfer system 140 moves the substrate out of the left cooling station 136L, while the substrate transfer system 140 is moving the substrate out of the left cooling station 136L, or shortly after the substrate transfer system 140 has moved the substrate out of the left cooling station 136L irrespective of whether coolant flow in the right side cooling station 136R is activated or deactivated; and (B) shortly before the substrate transfer system 140 moves the substrate out of the right cooling station 136R, while the substrate transfer system 140 is moving the substrate out of the right cooling station 136R, or shortly after the substrate transfer system 140 has moved the substrate out of the right cooling station 136R irrespective of whether coolant flow in the left side cooling station 136L is activated or deactivated.

Alternatively, in some examples of this technology, two cooling stations 136L and 136R in a single load-lock module 412 need not share a common substrate transfer system 140. Rather, in some examples of this technology, separate left substrate transfer system 140L and right substrate transfer system 140R could be provided, one for each side. Additionally or alternatively, rather than a side-by-side (or left and right) arrangement, the two cooling stations 136L and 136R could be oriented as “upper” and “lower” cooling stations, and the “upper” and “lower” cooling stations may share a common substrate transfer system 140 or utilize separate substrate transfer systems 140L and 140R. When two substrate transfer systems 140R and 140L are provided in a single load-lock module, each can be in electronic communication with a single coolant supply control system 150.

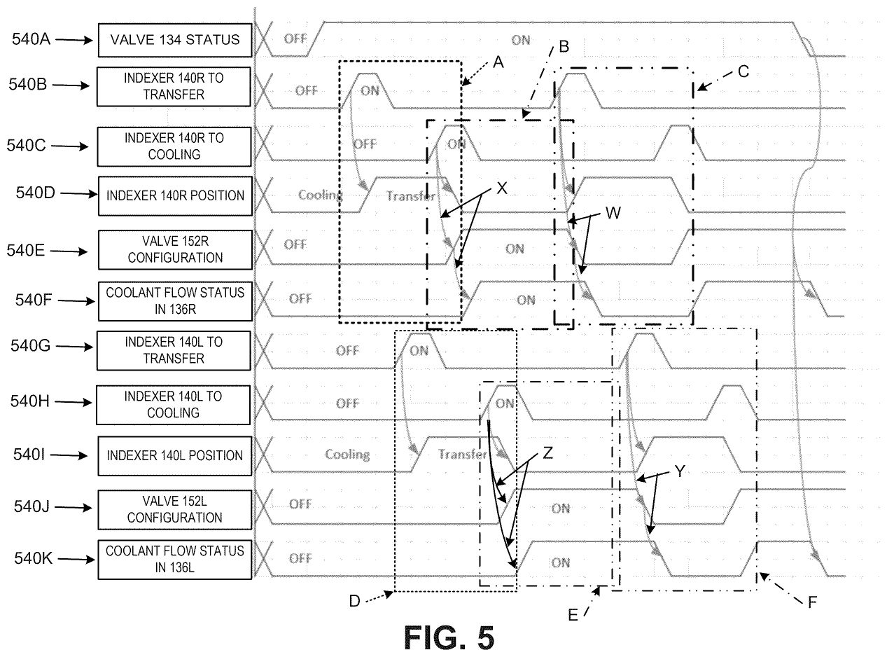

FIG. 5 illustrates features of example operation of cooling system 130 of the types described above in conjunction with FIG. 4. The same or similar operations could be used in conjunction with other substrate processing systems having at least two cooling stations (whether or not those cooling stations are in a single load-lock module). As shown in FIG. 5: (a) time line 540A illustrates operation of the main coolant shutoff 134 (e.g., when scheduler or other substrate processing system 200 software sends commands to turn main coolant shutoff valve 134 OFF and ON); (b) time line 540B illustrates when the scheduler or other substrate processing system 200 software sends commands to a right substrate transfer system 140R to initiate a move to its transferring position; (c) time line 540C illustrates when the scheduler or other substrate processing system 200 software sends commands to the right substrate transfer system 140R to initiate a move to its cooling position; (d) time line 540D illustrates the position of the right substrate transfer system 140R—either in its cooling position or its transferring position; (e) time line 540E illustrates the status of the right controllable valve 154R—in its closed configuration (OFF) or its open configuration (ON); and (f) time line 540F illustrates the status of coolant flow through the right cooling station 136R—OFF (not flowing) or ON (flowing).

Further, as shown in FIG. 5: (a) time line 540G illustrates when the scheduler or other substrate processing system 200 software sends commands to a left substrate transfer system 140L to initiate a move to its transferring position; (b) time line 540H illustrates when the scheduler or other substrate processing system 200 software sends commands to the left substrate transfer system 140L to initiate a move to its cooling position; (c) time line 540I illustrates the position of the left substrate transfer system 140L—either in its cooling position or its transferring position; (d) time line 540J illustrates the status of the left controllable valve 154L—in its closed configuration (OFF) or its open configuration (ON); and (e) time line 540K illustrates the status of coolant flow through the left cooling station 136L—OFF (not flowing) or ON (flowing).

As shown in FIG. 5, when the right substrate transfer system 140R is commanded to go to the transfer position (time line 540B switching to ON) and while it is at the transfer position (time line 540D at “Transfer”), the right controllable valve 152R is OFF (time line 540E) and coolant is not flowing in the right cooling station 136R (time line 540F at OFF). See box A in FIG. 5. But when the right substrate transfer system 140R is commanded to go to the cooling position (time line 540C going to the ON position): (i) the right substrate transfer system 140R changes to the “Cooling” position (time line 540D), (ii) the right controllable valve 152R moves to ON (time line 540E), and (iii) coolant begins flowing through the right cooling system 130R (time line 540F). See box B in FIG. 5.

Coolant continues flowing in the right cooling station 136R in this example until the substrate transfer system 140R receives a command to move to the “Transfer” position. This activity: (a) causes the coolant supply control system 150 to change the controllable valve 152R to its closed configuration (time line 540E moves to OFF), which (b) deactivates the flow of coolant to right cooling station 136R (time line 540F moves to OFF). See box C in FIG. 5. Other instances of changing coolant flow in the right cooling station 136R are shown in time lines 540A-540F in FIG. 5.

Thus, as shown in FIG. 5, coolant does not flow continuously through the right cooling station 136R. Rather, coolant flow is limited to times while a substrate is located at the cooling position and/or is headed toward the cooling position (as shown by the position of the substrate transfer system 140R in time line 540D). In this specific example: (a) a command (e.g., input data from the scheduler software or other control source to coolant supply control system 150) to the substrate transfer system 140R to move to the transfer position triggers the coolant supply control system 150 of this example system and method to change the controllable valve 152R to its closed configuration, which stops coolant flow through right cooling station 136R (see arrows W in FIG. 5), and (b) a command (e.g., input data from the scheduler software or other control source to coolant supply control system 150) to the substrate transfer system 140R to move to the cooling position triggers the coolant supply control system 150 of this example system and method to change the controllable valve 152R to its open configuration, which activates coolant flow through right cooling station 136R (see arrows X in FIG. 5).

As further shown in FIG. 5, when the left substrate transfer system 140L is commanded to go to its transfer position (time line 540G switching to ON) and while it is at the transfer position (time line 540I at “Transfer”), the left controllable valve 152L is OFF (time line 540J) and coolant is not flowing in the left cooling station 136L (time line 540K at OFF). See box D in FIG. 5. But when the left substrate transfer system 140L is commanded to go to the cooling position (time line 540H going to the ON position): (i) the left substrate transfer system 140L changes to the “Cooling” position (time line 540I), (ii) the left controllable valve 152L moves to ON (time line 540J), and (iii) coolant begins flowing through the left cooling station 136L (time line 540K). See box E in FIG. 5.

Coolant continues flowing in the left cooling station 136L in this example until the substrate transfer system 140L receives a command to move to the “Transfer” position. This activity: (a) causes the coolant supply control system 150 to change the controllable valve 152L to its closed configuration (time line 540J moves to OFF), which (b) deactivates the flow of coolant to the left cooling station 136L (time line 540K moves to OFF). See box F in FIG. 5. Other instances of changing coolant flow in the left cooling station 136L are shown in time lines 540G-540K in FIG. 5.

Thus, as shown in FIG. 5, coolant does not flow continuously through the left cooling station 136L. Rather, coolant flow is limited to times while a substrate is located at the cooling position and/or is headed toward the cooling position (as shown by the position of the substrate transfer system 140L in time line 540I). In this specific example: (a) a command (e.g., input data from the scheduler software or other control source to coolant supply control system 150) to the substrate transfer system 140L to move to the transfer position triggers the coolant supply control system 150 of this example system and method to change the controllable valve 152L to its closed configuration, which stops coolant flow through left cooling station 136L (see arrows Y in FIG. 5), and (b) a command (e.g., input data from the scheduler software or other control source to coolant supply control system 150) to the substrate transfer system 140L to move to the cooling position triggers the coolant supply control system 150 of this example system and method to change the controllable valve 152L to its open configuration, which activates coolant flow through left cooling station 136L (see arrows Z in FIG. 5).

Further, as shown in FIG. 5, coolant flows in the right cooling station 136R and left cooling station 136L are independent of one another. This is due to independent operation of controllable valves 152R and 152L by coolant supply control system 150. Compare time lines 540E and 540J and time lines 540F and 540K for examples of this independent operation.

While the description of FIGS. 4 and 5 identifies features of “right” and “left” components of cooling stations and their associated equipment, information in FIGS. 4 and 5 applies equally as well to two cooling stations in other arrangements, such as: (a) in a single load-lock module or other chamber but in an “upper” and “lower” arrangement and/or configuration and/or (b) in two separate load-lock modules or chambers of a substrate processing system. Thus, the use of the terms “left” and “right” and the designators “L” and “R” in the description above is for convenience, to ease identification of different components. Unless expressly stated, the terms “left” and “right” and the designators “L” and “R” used herein should not be construed as requiring a specific side-by-side arrangement of parts and/or an arrangement of parts in a single load-lock module and/or other chamber.

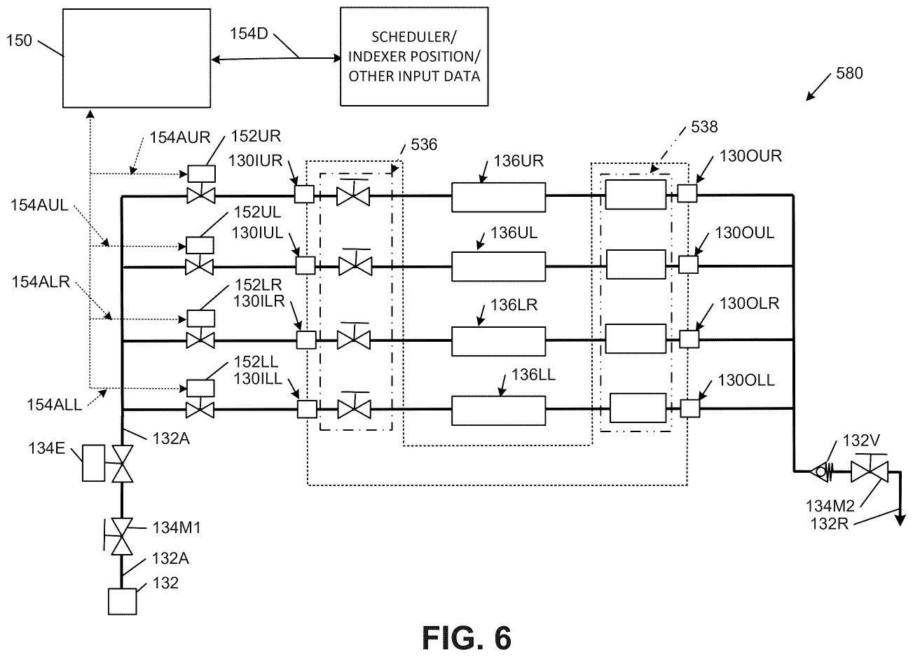

As additional or alternative example features, as schematically illustrated in FIG. 6, a single load-lock module (e.g., 412) may include a second set of cooling stations so that the load-lock module 412 has four total cooling stations. This second set of cooling stations may be vertically displaced from the other set within the load-lock module 412 (e.g., upward or downward from the example side-by-side arrangement shown in FIG. 4), such that the load-lock module 412 includes an “upper” pair of cooling stations (e.g., upper left cooling station 136UL and upper right cooling station 136UR sharing a first substrate transfer system (e.g., 140) like the arrangement shown in FIG. 4) and a “lower” pair of cooling stations (e.g., lower left cooling station 136LL and lower right cooling station 136LR sharing a second, separate substrate transfer system (e.g., 140) like the arrangement shown in FIG. 4). Such example upper and lower cooling stations may share: (a) a single coolant source 132; (b) a single set of main shutoffs 134M1 and 134E (described below); and (c) a single coolant supply control system 150 (the components shown within the dashed box 450 shown in FIG. 4). The cooling stations 136UR, 136UL, 136LR, and 136LL may constitute part of a single cooling system 130 or four separate cooling systems, or two or more cooling stations (in any combination) may be considered as part of one cooling system.

FIG. 6 schematically illustrates an example of a system that includes four cooling stations 136UL, 136UR, 136LL, and 136LR, e.g., of the types described above). Where the same reference number or reference number root is used in FIG. 6 as used for the reference number or reference number root in FIGS. 1-5 and/or the discussion above, the same or similar part is being referenced (including any features, options, or alternatives for that part), and much of the duplicative description thereof may be omitted.

As shown in the example of FIG. 6, this system 580 includes four independent coolant inlets (130IUL, 130IUR, 130ILL, 130ILR—one for each cooling station) and four independent coolant outlets (130OUL, 130OUR, 130OLL, 130OLR—one for each cooling station). The outlets 130OUL, 130OUR, 130OLL, 130OLR connect to a common coolant return line 132R. The example system 580 further includes: (a) four manual coolant shutoffs (one for each cooling station) are shown in the region labeled by dot-dash line 536 and (b) four flow meters for providing coolant flow rate data (one for each cooling station) are shown in the region labeled by double dot-dash line 538.

The main coolant supply line 132A from the source 132 includes a manual shutoff 134M1 and an electronically controllable shutoff 134E. Further, the coolant return line 132R includes a shutoff 134M2 (e.g., a manual shutoff) and a backflow preventing check valve 132V. The coolant return line 132R may transfer coolant to an appropriate location, e.g., to be recycled, for other uses, etc.

The system 580 of FIG. 6 further shows that the coolant inlets 130IUL, 130IUR, 130ILL, 130ILR of each of the four cooling stations 136UL, 136UR, 136LL, and 136LR, respectively, receive coolant via an independently operable controllable valve 152UR, 152UL, 152LR, and 152LL, respectively. These controllable valves 152UR, 152UL, 152LR, and 152LL may have the features and/or operations described above for controllable valves 152, 152L, and 152R. These controllable valves 152UR, 152UL, 152LR, 152LL are independently operable to switch between their open configuration and closed configuration by data transmitted from coolant supply control system 150 via data lines 154AUR, 154AUL, 154ALR, and 154ALL, respectively.

The controllable valves 152UR, 152UL, 152LR, and 152LL of this example may be independently controllable in any of the manners described above in conjunction with FIGS. 3 and 5 (and the others) such that coolant flow through the respective cooling station 136UL, 136UR, 136LL, and 136LR is limited to times while a substrate is located in that specific cooling station 136UL, 136UR, 136LL, or 136LR (e.g., located on or moving toward its cooling plate 130P). Additionally or alternatively, in at least some examples, coolant may flow through a cooling station (e.g., controllable valves 152UR, 152UL, 152LR, and/or 152LL for that respective cooling station may be opened) for time periods shortly before arrival of the substrate at that specific cooling station and/or shortly after the substrate has exited that specific cooling station (with “shortly” having the meaning described above).

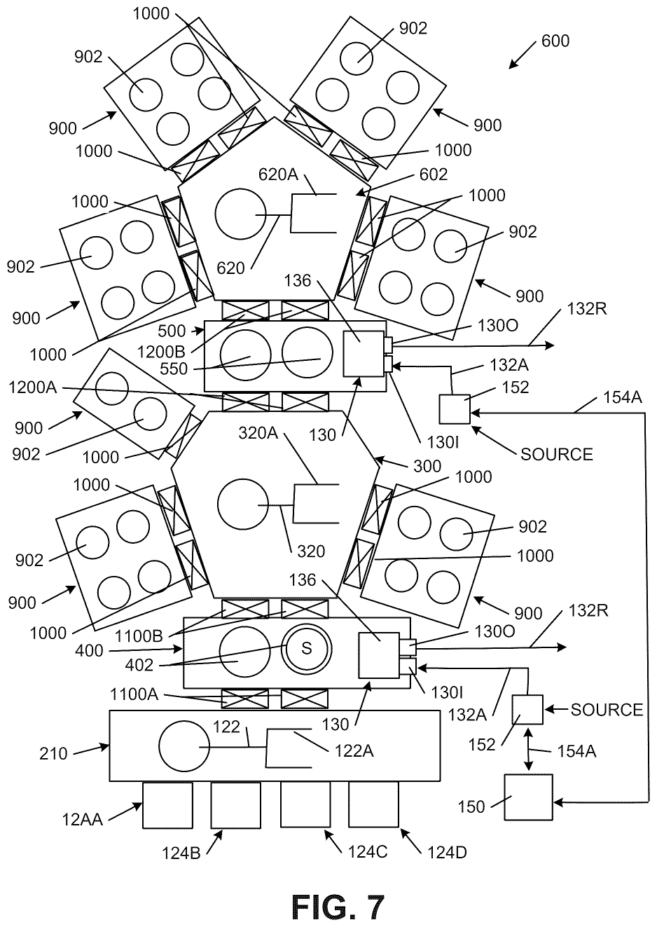

While the description of FIG. 6 identifies features of the four noted cooling stations in a single load-lock module (e.g., 412), information in FIG. 6 applies equally as well to multiple cooling stations in other arrangements, such as: (a) in a single load-lock module or other chamber but in an arrangement other than having two “upper” and two “lower” arrangements and configurations and/or (b) in two or more separate load-lock modules or chambers of a substrate processing system (e.g., of the types shown in FIG. 7 described below). Thus, the use of the terms “left,” “right,” “upper,” and “lower” and the designators “L,” “R,” “U,” and “L” in the description above is for convenience, to ease identification of different components. Unless expressly stated, the terms “left,” “right,” “upper,” and “lower” and the designators “L,” “R,” “U,” and “L” used herein should not be construed as requiring a specific 2×2 side-by-side and top/bottom arrangement of parts and/or an arrangement of parts in a single load-lock module and/or other chamber.

FIG. 7 schematically illustrates an overhead view of another example substrate processing system 600 (e.g., a cluster type semiconductor processing system) according to some aspects of this technology. This substrate processing system 600 has expanded substrate processing capabilities. Where the same reference number is used in FIG. 7 as used in FIGS. 1-6 described above, the same or similar part is being referenced, and much of the duplicative description may be omitted.

This example substrate processing system 600 expands substrate processing capabilities (e.g., as compared to the substrate processing system 200 of FIG. 1) at least by adding an additional substrate handling chamber and one or more additional substrate processing chambers. Aspects of the present technology may be used with substrate processing systems having expanded substrate processing capabilities of the types described in U.S. Patent Appln. Publn. No. 2025/0006521 A1 filed Jun. 26, 2024, which patent application and publication are entirely incorporated herein by reference.

As shown in FIG. 7, this example substrate processing system 600 includes: (a) a first substrate handling chamber 300 (an “inboard” substrate handling chamber) including a first robotic arm 320 having an end effector 320A; (b) a first load-lock module 400 (an “inboard” load-lock module) connected at one edge or facet of the first substrate handling chamber 300; (c) a second load-lock module 500 (an “outboard” load-lock module) connected at the opposite edge or facet of the first substrate handling chamber 300; and (d) a second substrate handling chamber 602 (an “outboard” substrate handling chamber) including a second robotic arm 620 having an end effector 620A. The second load-lock module 500 extends between and connects the first substrate handling chamber 300 and the second substrate handling chamber 602. In this example, load-lock modules 400 and 500 may include cooling system features in accordance with aspects of this technology, as will be described in more detail below.

The first load-lock module 400 of this example also is connected with an equipment front end module 210. This front end module 210 includes a third robotic arm 122 having an end effector 122A. The equipment front end module 210 may include a purge gas source for providing an inert gas atmosphere within the equipment front end module 210. The equipment front end module 210 receives new substrates for processing into the substrate processing system 600 and discharges processed substrates from the substrate processing system 600 via one or more load ports 124A-124D (moving the substrates between the load port(s) 124A-124D and the first load-lock module 400 using the robotic arm 122). While four load ports 124A-124D are shown in the example of FIG. 7, more or fewer load ports may be provided in other specific examples of this technology.

Each of the first substrate handling chamber 300 and the second substrate handling chamber 602 is engaged with multiple substrate processing chambers 900. Substrates S are transferred into the substrate processing chambers 900 where one or more layers of material are deposited onto a surface of the substrate and/or other desired substrate processing takes place. FIG. 7 shows several substrate processing chambers 900 including four substrate supports 902 onto which substrates can be placed during processing. More or fewer substrates supports 902 may be provided in the substrate processing chambers 900 (e.g., with one of the substrate processing chambers 900 connected to inboard substrate handling chamber 300 having two substrate supports 902 shown). Each of the substrate processing chambers 900 may have the same structures or one or more of the substrate processing chambers 900 may have a different structure from other substrate processing chambers 900 present.

Each of the first substrate handling chamber 300 and the second substrate handling chamber 602 is connected with its respective substrate processing chambers 900 via one or more gate valves 1000. While one or two gate valves 1000 are shown connecting substrate handling chambers 300, 602 with each of their respective substrate processing chambers 900, more or fewer gate valves 1000 may be provided with each substrate processing chamber 900, in other examples of this technology. When closed, the gate valves 1000 sealingly separate the substrate handling chambers 300, 602 from their respective substrate processing chambers 900 (so that independent atmospheric conditions may be maintained in each chamber). When open, the gate valves 1000 provide an opening (e.g., a substrate transfer slot) through which the end effector 320A, 620A of a robotic arm 320, 620 can extend to move substrates into and out of the substrate processing chamber 900. Each of gate valves 1000 may have the same structures or one or more of the gate valves 1000 may have a different structure from other gate valves 1000 present.

One face of the first load-lock module 400 connects with the equipment front end module 210 by one or more gate valves 1100A (two shown in FIG. 7), and the opposite face of the first load-lock module 400 connects with the first substrate handling chamber 300 by one or more gate valves 1100B (two shown in FIG. 7). The first load-lock module 400 further includes one or more substrate supports 402 (e.g., “setplates,” two shown in FIG. 7) for holding substrates while they wait to be moved into the equipment front end module 210 or the first substrate handling chamber 300. When closed, the gate valves 1100A, 1100B sealingly separate the first load-lock module 400 from the equipment front end module 210 and the substrate handling chamber 300 (so that independent atmospheric conditions may be maintained in each chamber). When open, the gate valves 1100A provide an opening (e.g., a substrate transfer slot) through which the end effector 122A of robotic arm 122 can extend to move substrates into and out of the equipment front end module 210. When open, the gate valves 1100B provide an opening (e.g., a substrate transfer slot) through which the end effector 320A of robotic arm 320 can extend to move substrates into and out of the substrate handling chamber 300. Each of gate valves 1100A, 1100B may have the same structure or one or more of the gate valves 1100A, 1100B may have a different structure from other gate valves 1100A, 1100B, 1000 present.

In the substrate processing system 600 of FIG. 7, one face of the second load-lock module 500 connects with the first substrate handling chamber 300 by one or more gate valves 1200A (two shown in FIG. 7), and the opposite face of the second load-lock module 500 connects with the second substrate handling chamber 602 by one or more gate valves 1200B (two shown in FIG. 7). The second load-lock module 500 further includes one or more substrate supports 550 (e.g., “setplates,” two shown in FIG. 7) for holding substrates while they wait to be moved between the two substrate handling chambers 300, 602. When closed, the gate valves 1200A, 1200B sealingly separate the second load-lock module 500 from the two substrate handling chambers 300, 602 (so that independent atmospheric conditions may be maintained in each chamber). When open, the gate valves 1200A provide an opening (e.g., a substrate transfer slot) through which the end effector 320A of robotic arm 320 can extend to move substrates into and out of the first substrate handling chamber 300. When open, the gate valves 1200B provide an opening (e.g., a substrate transfer slot) through which the end effector 620A of robotic arm 620 can extend to move substrates into and out of the second substrate handling chamber 602. Each of gate valves 1200A, 1200B may have the same structure or one or more of the gate valves 1200A, 1200B may have a different structure from other gate valves 1200A, 1200B present. Gate valves 1200A and/or 1200B also may have the same or different structures from gate valves 1100A and/or 1100B and/or from gate valves 1000.

The first load-lock module 400 may have the same structure as the second load-lock module 500 and/or the first and second load-lock modules 400, 500 may be interchangeable (e.g., so that load-lock modules 400, 500 can switch positions and/or have a modular structure). In other examples, the first load-lock module 400 and the second load-lock module 500 may have different structures and/or may not be interchangeable (e.g., so that load-lock modules 400, 500 cannot switch positions in the substrate processing system 100).

In the substrate processing system 600 of FIG. 7, each of the first load-lock module 400 and the second load-lock module 500 may include one or more cooling systems (e.g., 130) and/or one or more cooling stations (e.g., 136). The cooling systems 130 may be provided within or as part of the load-lock module 400 and/or 500, or they may be directly accessible from the load-lock module 400 and/or 500 (e.g., as a component connected to the load-lock module 400 and/or 500, such as via a gate valve arrangement).

Further in the example of FIG. 7, each of load-lock module 400 and load-lock module 500 includes a cooling system 130 having an inlet 130I for coolant flow into the cooling station 136 and cooling system 130 and an outlet 130O for coolant flow out of the cooling station 136 and cooling system 130 (via coolant return line 132R).

Further, each of load-lock module 400 and load-lock module 500 includes a controllable valve 152 that is controllable by coolant supply control system 150 using control data transmitted via data transmission line 154A (e.g., by a wired or wireless connection). Alternatively, if desired, separate coolant supply control systems 150 could be provided for the inboard load-lock module 400 and the outboard load-lock module 500. Coolant from a source (e.g., a single source or independent sources) is provided to the controllable valves 152, and each controllable valve 152 is controlled independently (e.g., via coolant supply control system 150) so as to allow coolant to flow to that specific cooling system 130 and/or to that specific cooling station 136 during limited times, e.g., times while a substrate is present (or scheduled to be present) in that specific cooling system 130 and/or cooling station 136 (and/or, in some examples, from a time period shortly before or shortly after the substrate arrives, and/or until a time period shortly before or shortly after the substrate leaves).

The cooling systems 130 in the load-lock modules 400 and/or 500 of FIG. 7 may have any of the features, components, alternatives, and/or options as described above for the cooling systems of FIGS. 1-6. Thus, each cooling system 130 may have one or more cooling stations 136 associated with it (e.g., arranged side-by-side, “upper” and “lower,” and/or in another manner). Additionally or alternatively, the cooling systems 130 in the load-lock modules 400 and/or 500 of FIG. 7—including coolant supply control system 150 and controllable valves 152—may be operated in any of the manners described above for the cooling systems of FIGS. 1-6.

Each cooling station 136 (e.g., each of one to four cooling stations provided in cooling system 130 of inboard lock-load module 400 and each of one to four cooling stations provided in cooling system 130 of outboard lock-load module 500) is provided with its own controllable valve 152. That controllable valve 152 is independently controllable (by coolant supply control system 150) to independently control coolant flow within that specific cooling station and to correlate activation and deactivation of coolant flow through that specific coolant station with the presence and absence of a substrate in that cooling station (e.g., as described above). Coolant flow in each coolant station included in the example substrate processing system 600 of FIG. 7 operates independent of the status of coolant flow in the other coolant stations of substrate processing system 600.

As noted above, aspects of this technology may provide advantages in reducing coolant consumption and/or reducing the amount of coolant flow during substrate processing activities. In some examples of this technology, coolant usage may be reduced by at least 10% per cooling station, as compared to systems that use continuously flowing coolant, and in some examples, coolant usage may be reduced by at least 20%, at least 25%, or at least 30%. These features may save material costs (e.g., costs to replace coolant material and/or maintain the coolant supply) and/or processing costs (e.g., by reducing the volume of coolant that may need to be cooled for use, by reducing coolant pump usage (and other equipment usage), by reducing maintenance costs (and/or associated system downtime), etc.

The above description and the accompanying drawings show the cooling system(s), components thereof, and features thereof in accordance with aspects of this technology included within and/or associated with a load-lock module. Additionally or alternatively, aspects of this technology may be used and/or associated with other components (e.g., other chambers) of substrate processing systems (e.g., 200 and/or 600) where substrate cooling may be desired, such as in substrate handling chambers, equipment front end modules, etc.) Still additionally or alternatively, aspects of this technology may be used in environments and/or systems other than substrate processing systems. Thus, at least some examples of the present technology are not limited to use with load-lock modules.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present invention.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

The headings provided herein, if any, are for convenience only and do not necessarily affect the scope or meaning of the devices and methods disclosed herein.

1. A substrate processing system, comprising:
a substrate cooling system including a first substrate cooling station including: (i) a first substrate cooling plate, (ii) a first coolant inlet, (iii) a first coolant outlet, and (iv) a first heat conduction zone located between the first coolant inlet and the first coolant outlet, the first heat conduction zone configured to place coolant at a position to allow conductive heat transfer between the first substrate cooling plate and coolant located within the first heat conduction zone;
a first coolant supply line in fluid communication with the first coolant inlet;
a first valve changeable between: (a) an open configuration in which coolant flows through the first coolant supply line and into the first coolant inlet and (b) a closed configuration in which coolant flow through the first coolant supply line is stopped; and
a coolant supply control system programmed and configured: (i) to place the first valve in the open configuration in response to input data indicating that a substrate has moved to or will move to the first substrate cooling plate, and (ii) to place the first valve in the closed configuration in response to input data indicating that the substrate has moved or will move away from the first substrate cooling plate.

2. The substrate processing system according to claim 1, wherein the substrate cooling system further includes a second substrate cooling station including: (i) a second substrate cooling plate, (ii) a second coolant inlet, (iii) a second coolant outlet, and (iv) a second heat conduction zone located between the second coolant inlet and the second coolant outlet, the second heat conduction zone configured to place coolant at a position to allow conductive heat transfer between the second substrate cooling plate and coolant located within the second heat conduction zone,
wherein the substrate processing system further comprises:
a second coolant supply line in fluid communication with the second coolant inlet of the second substrate cooling station; and
a second valve changeable between: (a) an open configuration in which coolant flows through the second coolant supply line and into the second coolant inlet and (b) a closed configuration in which coolant flow through the second coolant supply line is stopped,
wherein the coolant supply control system further is programmed and configured: (i) to place the second valve in the open configuration in response to input data indicating that a substrate has moved to or will move to the second substrate cooling plate, and (ii) to place the second valve in the closed configuration in response to input data indicating that the substrate has moved or will move away from the second substrate cooling plate, and wherein the coolant supply control system controls the second valve independent of control of the first valve.

3. The substrate processing system according to claim 2, further comprising:
a first load-lock module, wherein the first substrate cooling station and the second substrate cooling station are located within or directly accessible from the first load-lock module;
a first substrate handling chamber engaged with the first load-lock module; and
a first substrate transfer arm configured to move substrates between the first load-lock module and the first substrate handling chamber.

4. The substrate processing system according to claim 3, further comprising:
one or more substrate processing chambers coupled with the first substrate handling chamber,
wherein the first substrate transfer arm further is configured to move substrates between the first substrate handling chamber and the one or more substrate processing chambers.

5. The substrate processing system according to claim 4, further comprising:
a second substrate handling chamber engaged with the first load-lock module; and
a second substrate transfer arm configured to move substrates between the first load-lock module and the second substrate handling chamber.

6. The substrate processing system according to claim 3, further comprising:
a second load-lock module coupled with the first substrate handling chamber, wherein the first substrate transfer arm further is configured to move substrates between the first substrate handling chamber and the second load-lock module.

7. The substrate processing system according to claim 6, further comprising:
a second substrate cooling system located within or directly accessible from the second load-lock module.

8. The substrate processing system according to claim 7, wherein the second substrate cooling system includes: (i) a second substrate cooling plate, (ii) a second coolant inlet, (iii) a second coolant outlet, and (iv) a second heat conduction zone located between the second coolant inlet and the second coolant outlet, the second heat conduction zone configured to place coolant at a position to allow conductive heat transfer between the second substrate cooling plate and coolant located within the second heat conduction zone,
wherein the substrate processing system further comprises:
a second coolant supply line in fluid communication with the second coolant inlet of the second substrate cooling station; and
a second valve changeable between: (a) an open configuration in which coolant flows through the second coolant supply line and into the second coolant inlet and (b) a closed configuration in which coolant flow through the second coolant supply line is stopped,
wherein the coolant supply control system further is programmed and configured: (i) to place the second valve in the open configuration in response to input data indicating that a substrate has moved to or will move to the second substrate cooling plate, and (ii) to place the second valve in the closed configuration in response to input data indicating that the substrate has moved or will move away from the second substrate cooling plate.

9. A substrate processing system, comprising:
a substrate cooling system including:
a first substrate cooling station including: (i) a first substrate cooling plate, (ii) a first coolant inlet, (iii) a first coolant outlet, and (iv) a first heat conduction zone located between the first coolant inlet and the first coolant outlet, the first heat conduction zone configured to place coolant at a position to allow conductive heat transfer between the first substrate cooling plate and coolant located within the first heat conduction zone, and
a second substrate cooling station including: (i) a second substrate cooling plate, (ii) a second coolant inlet, (iii) a second coolant outlet, and (iv) a second heat conduction zone located between the second coolant inlet and the second coolant outlet, the second heat conduction zone configured to place coolant at a position to allow conductive heat transfer between the second substrate cooling plate and coolant located within the second heat conduction zone;
a first coolant supply line in fluid communication with the first coolant inlet;
a second coolant supply line in fluid communication with the second coolant inlet;
a first valve changeable between: (a) an open configuration in which coolant flows through the first coolant supply line and into the first coolant inlet and (b) a closed configuration in which coolant flow through the first coolant supply line is stopped; and
a second valve changeable between: (a) an open configuration in which coolant flows through the second coolant supply line and into the second coolant inlet and (b) a closed configuration in which coolant flow through the second coolant supply line is stopped.

10. The substrate processing system according to claim 9, further comprising:
a coolant supply control system in electronic communication with the first valve and in electronic communication with the second valve, wherein the coolant supply control system is configured: (i) to change the first valve from the open configuration to the closed configuration in response to activity indicating a substrate has or will move away from the first substrate cooling plate, (ii) to change the first valve from the closed configuration to the open configuration in response to activity indicating a substrate has or will move to the first substrate cooling plate, (iii) to change the second valve from the open configuration to the closed configuration in response to activity indicating a substrate has or will move away from the second substrate cooling plate, and (iv) to change the second valve from the closed configuration to the open configuration in response to activity indicating a substrate has or will move to the second substrate cooling plate.

11. The substrate processing system according to claim 9, further comprising:
a substrate transfer system configured: (a) to move substrates into and out of the first substrate cooling station, and (b) to move substrates into and out of the second substrate cooling station; and
a coolant supply control system in electronic communication with the first valve and in electronic communication with the second valve, wherein the coolant supply control system is configured: (i) to switch the first valve to the open configuration in response to input data indicating that the substrate transfer system has moved or will move a substrate to the first substrate cooling station, (ii) to switch the first valve to the closed configuration in response to input data indicating that the substrate transfer system has moved or will move a substrate out of the first substrate cooling station, (iii) to switch the second valve to the open configuration in response to input data indicating that the substrate transfer system has moved or will move a substrate to the second substrate cooling station, and (iv) to switch the second valve to the closed configuration in response to input data indicating that the substrate transfer system has moved or will move a substrate out of the second substrate cooling station.

12. The substrate processing system according to claim 9, further comprising:
a first load-lock module, wherein the first substrate cooling station and the second substrate cooling station are located within or directly accessible from the first load-lock module;
a first substrate handling chamber engaged with the first load-lock module; and
a first substrate transfer arm configured to move substrates between the first load-lock module and the first substrate handling chamber.

13. The substrate processing system according to claim 12, further comprising:
one or more substrate processing chambers coupled with the first substrate handling chamber,
wherein the first substrate transfer arm further is configured to move substrates between the first substrate handling chamber and the one or more substrate processing chambers.

14. The substrate processing system according to claim 13, further comprising:
a second substrate handling chamber engaged with the first load-lock module; and
a second substrate transfer arm configured to move substrates between the first load-lock module and the second substrate handling chamber.

15. The substrate processing system according to claim 14, further comprising:
one or more additional substrate processing chambers coupled with the second substrate handling chamber, wherein the second substrate transfer arm further is configured to move substrates between the second substrate handling chamber and the one or more additional substrate processing chambers.

16. The substrate processing system according to claim 12, further comprising:
a second load-lock module coupled with the first substrate handling chamber, wherein the first substrate transfer arm further is configured to move substrates between the first substrate handling chamber and the second load-lock module.

17. The substrate processing system according to claim 16, further comprising:
a second substrate cooling system located within or directly accessible from the second load-lock module.

18. The substrate processing system according to claim 17, wherein the second substrate cooling system includes:
a third substrate cooling station including: (i) a third substrate cooling plate, (ii) a third coolant inlet, (iii) a third coolant outlet, and (iv) a third heat conduction zone located between the third coolant inlet and the third coolant outlet, the third heat conduction zone configured to place coolant at a position to allow conductive heat transfer between the third substrate cooling plate and coolant located within the third heat conduction zone, and
a fourth substrate cooling station including: (i) a fourth substrate cooling plate, (ii) a fourth coolant inlet, (iii) a fourth coolant outlet, and (iv) a fourth heat conduction zone located between the fourth coolant inlet and the fourth coolant outlet, the fourth heat conduction zone configured to place coolant at a position to allow conductive heat transfer between the fourth substrate cooling plate and coolant located within the fourth heat conduction zone;
a third coolant supply line in fluid communication with the third coolant inlet of the third substrate cooling station;
a fourth coolant supply line in fluid communication with the fourth coolant inlet of the fourth substrate cooling station;
a third valve changeable between: (a) an open configuration in which coolant flows through the third coolant supply line and into the third coolant inlet and (b) a closed configuration in which coolant flow through the third coolant supply line is stopped; and
a fourth valve changeable between: (a) an open configuration in which coolant flows through the fourth coolant supply line and into the fourth coolant inlet and (b) a closed configuration in which coolant flow through the fourth coolant supply line is stopped.

19. A substrate processing method, comprising:
placing a first substrate in a first substrate transfer system;
moving the first substrate to a first substrate cooling station using the first substrate transfer system,
wherein the first substrate cooling station includes a first substrate holding location and a first heat conduction zone;
activating coolant flow to move coolant through the first heat conduction zone in response to input data indicating that the first substrate has moved to or will move to the first substrate holding location; and
deactivating coolant flow through the first heat conduction zone in response to input data indicating that the first substrate has moved away from or will move away from the first substrate holding location.

20. The substrate processing method according to claim 19, further comprising:
moving the first substrate away from the first substrate holding location using the first substrate transfer system at least in part while coolant flow through the first heat conduction zone is deactivated;
thereafter placing a second substrate in the first substrate transfer system;
moving the second substrate to the first substrate holding location using the first substrate transfer system;
activating coolant flow to move coolant through the first heat conduction zone in response to input data indicating that the second substrate has moved to or will move to the first substrate holding location; and
deactivating coolant flow through the first heat conduction zone in response to input data indicating that the second substrate has moved away from or will move away from the first substrate holding location.

21. The substrate processing method according to claim 19, further comprising:
placing a second substrate in the first substrate transfer system;
moving the second substrate to a second substrate cooling station using the first substrate transfer system, the second substrate cooling station including a second substrate holding location and a second heat conduction zone;
activating coolant flow to move coolant through the second heat conduction zone in response to input data indicating that the second substrate has moved to or will move to the second substrate holding location; and
deactivating coolant flow through the second heat conduction zone in response to input data indicating that the second substrate has moved away from or will move away from the second substrate holding location.

22. The substrate processing method according to claim 19, further comprising:
placing a second substrate in a second substrate transfer system;
moving the second substrate to a second substrate cooling station using the second substrate transfer system, wherein the second substrate cooling station includes a second substrate holding location and a second heat conduction zone;
activating coolant flow to move coolant through the second heat conduction zone in response to input data indicating that the second substrate has moved to or will move to the second substrate holding location; and
deactivating coolant flow through the second heat conduction zone in response to input data indicating that the second substrate has moved away from or will move away from the second substrate holding location.

23. The substrate processing method according to claim 22, wherein coolant flow through the second heat conduction zone is controlled completely independent of control of coolant flow through the first heat conduction zone.
